(19) United States
(12) Patent Application Publication
(10) Pub. No.: US 2011/0192442 A1
(43) Pub. Date: Aug. 11, 2011

(54) PHOTOVOLTAIC MODULE WITH EMBEDDED JUNCTION BOX AND PHOTOVOLTAIC WINDOW WITH THE SAME

(75) Inventors: Szu-Han LI, Zhongli City (TW); Wei-Lun Hsiao, Taoyuan City (TW)

(73) Assignee: Du Pont Apollo Limited, Hong Kong (HK)

(21) Appl. No.: 13/018,385

(22) Filed: Jan. 31, 2011

Related U.S. Application Data
(60) Provisional application No. 61/302,296, filed on Feb. 8, 2010.

(51) Int. Cl. H01L 31/042

(52) U.S. Cl. 136/244

(57) ABSTRACT

A photovoltaic module with an embedded junction box and a photovoltaic window with the same are described. The photovoltaic module includes a photovoltaic panel having a first substrate and a second substrate, and an embedded junction box is fixed to a surface of the first substrate and an edge of the second substrate. The first substrate is longer than the second substrate to form an indentation on the first substrate to firmly fix the embedded junction box in the photovoltaic panel.

### RELATED APPLICATIONS

This application claims priority to U.S. Provisional Application Ser. No. 61/302,296, filed Feb. 8, 2010, which is herein incorporated by reference.

### FIELD OF THE INVENTION

The present invention generally relates to a photovoltaic module having a junction box. More particularly, this invention relates to a photovoltaic module having an embedded junction box.

### BACKGROUND OF THE INVENTION

The increasing scarcity, and the realization of the ecological and safety problems associated with non-renewable energy resources such as coal, petroleum and uranium, have made it essential that increased use be made of alternate non-depletable energy resources such as solar energy. Solar energy use has been limited in the past to special application due in part to the high cost of manufacturing devices capable of producing significant amounts of photovoltaic energy. The improvement in manufacture technology for fabricating the photovoltaic (PV) panel in mass production has greatly promoted the use of solar energy.

Photovoltaic modules including a plurality of photovoltaic cells are commercially available from many manufacturers in various sizes and power outputs. These cells are connected in a circuit (either series or parallel) for battery charging or other applications.

A photovoltaic cell can convert light energy into electric energy. The photovoltaic panel contains a plurality of photovoltaic cells. Each photovoltaic panel has a positive output and a negative output, and the positive output and the negative output of the photovoltaic panel are respectively connected to a common positive output wire and a common negative output wire with internal metallic ribbons and terminal metallic ribbons. After the positive and negative outputs are soldered onto the outside of the photovoltaic panel, it is necessary to connect the positive and negative outputs with positive output cable and negative output cable, respectively, to convey the electric current from the photovoltaic panel, such that the electric current can be used for its intended purpose.

To protect these soldered connections from damage or short circuit, a protective structure, commonly called as a “junction box”, is positioned and secured over these soldered connections and the junction box is filled with a protective sealant, such as epoxy, to cover and protect these soldered connections. Also, it is needless to say that the junction box has to be firmly attached onto the back sheet of the solar panel. However, the conventional junction box is protruding from the back sheet of the solar panel. Therefore, the appearance of the window with the photovoltaic panel having the conventional junction box is unsightly and the photovoltaic panel is difficult to transport.

### SUMMARY OF THE INVENTION

One objective of the present invention is to provide an embedded junction box to firmly fix the embedded junction box on the photovoltaic module and reduce the thickness of the photovoltaic module.

To achieve these and other advantages and in accordance with the objective of the present invention, as the embodiment broadly describes herein, the present invention provides a photovoltaic module. The photovoltaic module includes a photovoltaic panel having a first substrate and a second substrate, and an embedded junction box is fixed to a surface of the first substrate and an edge of the second substrate. The first substrate is longer than the second substrate to form an indentation on the first substrate to fix the embedded junction box in the indentation.

The thickness of the embedded junction box and the first substrate is similar to the thickness of the first substrate and the second substrate. The first substrate and the second substrate are both glass substrates. The photovoltaic module can further use an adhesive member to fix the embedded junction box to the photovoltaic panel. The adhesive member can be L-shaped.

Furthermore, the photovoltaic panel includes a first metallic ribbon and a second metallic ribbon fixed between the first substrate and the second substrate, and the first metallic ribbon and the second metallic ribbon are extending outwardly from the second substrate. In addition, the embedded junction box includes a first terminal and a second terminal to directly connect to the first metallic ribbon and the second metallic ribbon respectively, without a conventional internal metallic ribbon. Furthermore, a bypass diode is disposed between the first terminal and the second terminal.

The photovoltaic module can further use a first cable and a second cable to respectively connect to the first terminal and the second terminal. The embedded junction box includes a rectangular shell having at least one opening and at least one cover to seal the at least one opening.

In another aspect, the present invention provides a photovoltaic window includes a window frame and the foregoing photovoltaic module. The window frame holds the photovoltaic module as well as the embedded junction box.

Accordingly, the surfaces of the photovoltaic module and the photovoltaic window with the embedded junction box are smooth. The junction box is embedded in the indentation formed by the substrates. The adhesive strength between the embedded junction box and the photovoltaic panel is improved, and the appearances of the photovoltaic module and the photovoltaic window with the embedded junction box are more beautiful.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates an embodiment of a photovoltaic module with an embedded junction box according to the present invention; and

FIG. 2 illustrates a partial cross-sectional view of a photovoltaic window having a photovoltaic module with an embedded junction box according to the present invention.

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

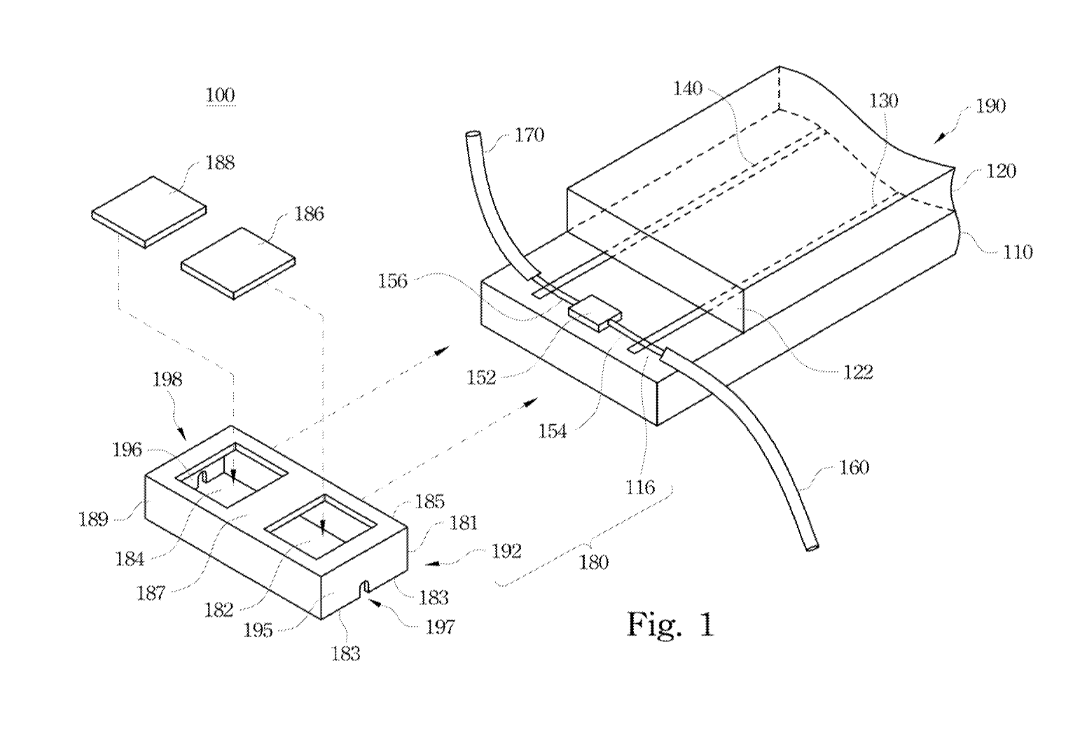

Refer to FIG. 1. FIG. 1 illustrates an embodiment of a photovoltaic module with an embedded junction box according to the present invention. The photovoltaic module 100 has a photovoltaic panel 190 and an embedded junction box 180 fixed on a first substrate 110 of the photovoltaic panel 190.

The photovoltaic panel 190 further includes a second substrate 120, a first metallic ribbon 130 and a second metallic ribbon 140. The first metallic ribbon 130 and the second metallic ribbon 140 are formed between the first substrate 110 and the second substrate 120, and extended from one edge of the second substrate 120 outwardly.

The junction box 180 includes a rectangular shell 192 having at least one opening 182/184 formed thereon and at least one cover 186/188 for covering the at least one opening 182/184. In the embodiment, the rectangular shell 192 comprises a first opening 182, a second opening 184, a first cover 186 and a second cover 188. The rectangular shell 192 is formed by a base portion 187, a first arm 185, a second arm 189, a first sidewall 195 and a second sidewall 196. The first opening 182 and the second opening 184 are formed on the base portion 187. The first cover 186 and the second cover 188 effectively seal the first opening 182 and the second opening 184 to protect the electronic connections therein, respectively.

The junction box 180 further includes a first terminal 154 to electrically and directly connect to the first metallic ribbon 130, a second terminal 156 to electrically and directly connect to the second metallic ribbon 140 by clamping or soldering, and a bypass diode 152 disposed between the first terminal 154 and the second terminal 156. Therefore, the first terminal 154 and the second terminal 156 can directly connect to the first metallic ribbon 130 and the second metallic ribbon 140 without the conventional internal metallic ribbon. The manufacturing process of the photovoltaic module 100 is effectively simplified. In addition, the first opening 182 and the second opening 184 are preferably aligned to the contact of the first terminal 154 and the first metallic ribbon 130, and the contact of the second terminal 156 and the second metallic ribbon 140 respectively to conveniently fix the contacts thereof.

The photovoltaic module 100 further includes a first cable 160 and a second cable 170 electrically connecting to the first terminal 154 and the second terminal 156 respectively in the junction box 180 to output the electric current from the photovoltaic module 100 to an electronic device (not shown) or connect to another photovoltaic module 100 in series or parallel. The first sidewall 195 and the second sidewall 196 respectively include a first hole 197 and a second hole 198 to allow the first cable 160 and the second cable 170 passing through the rectangular shell 192. The first hole 197 and the second hole 198 can be U-shaped holes or circle holes, which are not used to limit the scope of the invention.

Furthermore, the second substrate 120 has a length shorter than that of the first substrate 110 so as to form an indentation, and the junction box 180 is fixed in the indentation. The second substrate 120 includes a first fixing surface 122, an edge of the second substrate 120, and the first substrate 110 includes a second fixing surface 116 to adhere a first fixing surface 181 and a second fixing surface 183 of the U-shape shell 192 with an adhesive member.

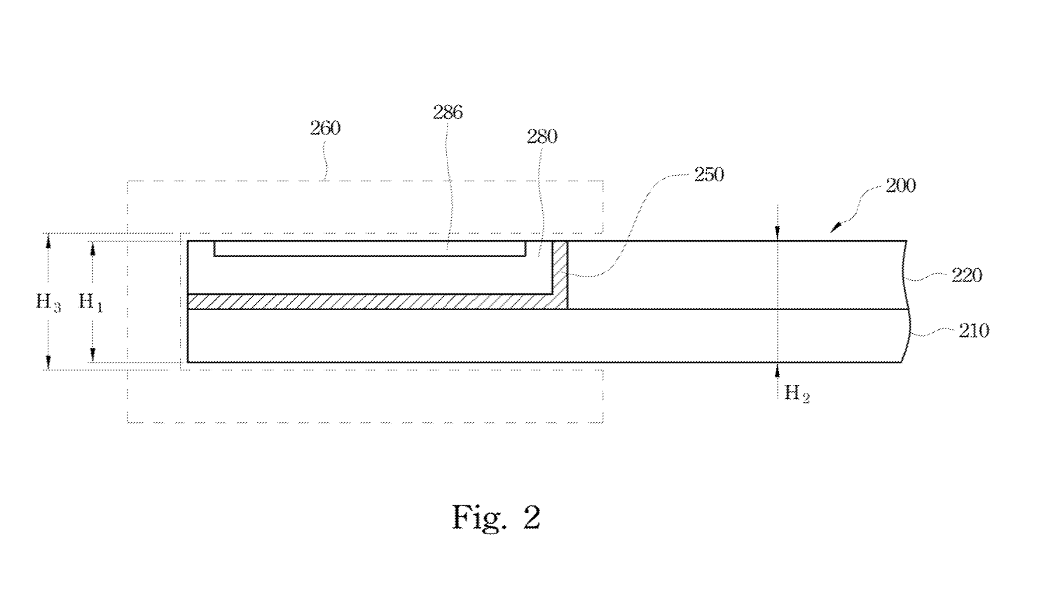

Further refer to FIG. 2. FIG. 2 illustrates a partial cross-sectional view of a photovoltaic window having a photovoltaic module with an embedded junction box according to the present invention. The photovoltaic window includes a photovoltaic module 200 having a first substrate 210, a second substrate 220, and a junction box 280 fixed into the indentation formed by the first substrate 210 and the second substrate 220 with an adhesive member 250. In other embodiment, the junction box 208 can be also fixed into the indentation by screw or other fixations, which is not used to limit the scope of the invention. The cover 286 covers the opening of the junction box 280. A window frame 260, such as a U-shaped window frame, can fix the photovoltaic module 200, and thus the junction box 280 can be further fixed inside the window frame. The thickness H₁ of the junction box 280, the adhesive member 250 and the first substrate 210 is similar to, preferably the same as, the thickness H₂ of the first substrate 210 and the second substrate 220. In addition, the width H₃ of the opening of the window frame 260 can be a little bit larger than the thickness H₁, or the width H₃ is the same as the thickness H₁. Therefore, the photovoltaic window having the photovoltaic module 200 with the embedded junction box 280 has no protruding element on the surface of the first substrate 210 and the second substrate 220 and the appearance thereof is more beautiful. In addition, the first substrate 210 is larger than the second substrate 220, and the junction box 280 is fixed to the surface of the first substrate 210 and the edge of the second substrate 220 with an L-shaped adhesive member 250 to effectively improve the adhesive strength of the embedded junction box 280 on the photovoltaic module 200.

Hence, the surfaces of the photovoltaic module and the photovoltaic window with the embedded junction box are smooth. Since the junction box is embedded in the indentation formed by the substrates, the adhesive strength between the embedded junction box and the photovoltaic panel is therefore improved. In addition, the appearances of the photovoltaic module and the photovoltaic window with the embedded junction box are more beautiful.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A photovoltaic module, comprising:
a photovoltaic panel having a first substrate and a second substrate, wherein the first substrate is longer than the second substrate; and
an embedded junction box fixed to a surface of the first substrate and an edge of the second substrate.

2. The photovoltaic module of claim 1, wherein a thickness of the embedded junction box and the first substrate is similar to a thickness of the first substrate and the second substrate.

3. The photovoltaic module of claim 1, wherein the first substrate and the second substrate are glass substrates.

4. The photovoltaic module of claim 1, further comprising an adhesive member disposed between the embedded junction box and the photovoltaic panel to fix the embedded junction box to the photovoltaic panel.

5. The photovoltaic module of claim 4, wherein the adhesive member is L-shaped.

6. The photovoltaic module of claim 1, wherein the photovoltaic panel further comprises a first metallic ribbon and a second metallic ribbon fixed between the first substrate and the second substrate, and extending from the second substrate.

7. The photovoltaic module of claim 6, wherein the embedded junction box further comprises a first terminal and a second terminal directly connected to the first metallic ribbon and the second metallic ribbon respectively.

8. The photovoltaic module of claim 7, wherein the embedded junction box further comprises a bypass diode disposed between the first terminal and the second terminal.

9. The photovoltaic module of claim 6, further comprising a first cable and a second cable respectively connected to the first terminal and the second terminal.

10. The photovoltaic module of claim 1, wherein the embedded junction box comprises a rectangular shell having at least one opening and at least one cover to seal the at least one opening.

11. A photovoltaic window, comprising:
a window frame; and
a photovoltaic module fixed in the window frame, wherein the photovoltaic module comprises:
a photovoltaic panel having a first substrate and a second substrate, wherein the first substrate is longer than the second substrate; and
an embedded junction box fixed to a surface of the first substrate and an edge of the second substrate, wherein the embedded junction box and the photovoltaic panel are held by the window frame.

12. The photovoltaic window of claim 11, wherein a thickness of the embedded junction box and the first substrate is similar to a thickness of the first substrate and the second substrate.

13. The photovoltaic window of claim 11, wherein the first substrate and the second substrate are glass substrates.

14. The photovoltaic window of claim 11, wherein the photovoltaic module further comprises an adhesive member disposed between the embedded junction box and the photovoltaic panel to fix the embedded junction box to the photovoltaic panel.

15. The photovoltaic window of claim 14, wherein the adhesive member is L-shaped.

16. The photovoltaic window of claim 11, wherein the photovoltaic panel further comprises a first metallic ribbon and a second metallic ribbon fixed between the first substrate and the second substrate, and extending from the second substrate.

17. The photovoltaic window of claim 16, wherein the embedded junction box further comprises a first terminal and a second terminal directly connected to the first metallic ribbon and the second metallic ribbon respectively.

18. The photovoltaic window of claim 17, wherein the embedded junction box further comprises a bypass diode disposed between the first terminal and the second terminal.

19. The photovoltaic window of claim 16, further comprising a first cable and a second cable respectively connected to the first terminal and the second terminal.

20. The photovoltaic window of claim 11, wherein the embedded junction box comprises a rectangular shell having at least one opening and at least one cover to seal the at least one opening.
